(19) United States
(12) Patent Application Publication
(10) Pub. No.: US 2021/0233787 A1
(43) Pub. Date: Jul. 29, 2021

(54) WARP MEASUREMENT DEVICE, VAPOR DEPOSITION APPARATUS, AND WARP MEASUREMENT METHOD

(71) Applicant: NuFlare Technology, Inc., Kanagawa (JP)

(72) Inventor: Yasushi IYECHIKA, Matsudo (JP)

(21) Appl. No.: 17/151,963

(22) Filed: Jan. 19, 2021

(30) Foreign Application Priority Data
Jan. 27, 2020 (JP) 2020-011187

(51) Int. Cl. H01L 21/67; C23C 16/52; C23C 16/34; G01B 11/16

(52) U.S. Cl. CPC H01L 21/67288; G01B 11/16; C23C 16/34; C23C 16/52

(57) ABSTRACT

A warp measurement device includes: a light emitter that emits two optical signals having different polarization directions to an object to be measured; a light receiver that receives, at different timings, the two optical signals reflected on the object to be measured; a warp detector that detects a warp of the object to be measured based on locations where the two optical signals are received on the light receiver; and a light selector that is disposed in an optical path of the two optical signals, alternately selects the two optical signals, and guides the two optical signals into the optical path.

### CROSS REFERENCE TO RELATED APPLICATIONS

This application is based upon and claims the benefit of priority from the prior Japanese Patent Application No. 2020-11187, filed on Jan. 27, 2020, the entire contents of which are incorporated herein by reference.

### FIELD

Embodiments of the present disclosure relates to a warp measurement device, a vapor deposition apparatus, and a warp measurement method.

### BACKGROUND

In manufacturing, electronic devices or light emitting diodes (LEDs) using compound semiconductors such as GaN, the epitaxial growth techniques are used to grow monocrystalline thin films on a monocrystalline substrate such as a silicon substrate.

Vapor deposition apparatuses are used in the epitaxial growth techniques. A vapor deposition apparatus includes a deposition chamber that is maintained to have an atmospheric pressure or a reduced pressure, a wafer being put in the deposition chamber. A material gas used for depositing a film is supplied into the deposition chamber while the wafer is being heated. As a result, a thermal decomposition reaction and a hydrogen reduction reaction are caused to the material gas on the surface of the wafer, whereby an epitaxial film is formed on the wafer.

Since such factors as the deposition temperature, the lattice constant, and the thermal expansion coefficient differ in each film formed on a wafer, sometimes the wafer may be warped while the films are being formed due to the difference in lattice constant between the films. The degree of the warp of the wafer changes depending on the deposition temperature, the materials for forming the films and the combination of the materials for forming the films.

Therefore, techniques for optically measuring the amount of the warp of the wafer and adjusting the film deposition conditions depending on the measured warp amount are proposed. In such techniques, the wafer warp amount is measured by emitting two laser beams to the wafer, receiving the two laser beams reflected on the wafer by means of a light receiving unit, and detecting the wafer warp amount based on the difference in the locations where the two laser beams are received.

If the wafer warp amount is large, the above method may not be able to measure the wafer warp amount correctly since the two laser beams reflected on the wafer may intersect with each other, and therefore which of the detected locations on the light receiving unit corresponds to which of the two laser beams cannot be determined. To deal with such a problem, methods for measuring a wafer warp using two laser beams having different polarization directions are proposed. In such methods, the laser beams are identified based on their polarization directions even if the two laser beams reflected on the wafer intersect each other. Therefore, the locations of the received laser beams may be detected by separate light receiving units.

However, the optical structures used in such methods become complicated since to measure the wafer warp using two laser beams having different polarization directions, a polarizing beam splitter for separating the two laser beams and light receiving units for receiving the respective light beams are required.

### BRIEF DESCRIPTION OF THE DRAWINGS

FIG. 1 illustrates a schematic configuration of a vapor deposition apparatus according to a first embodiment.

FIG. 2 illustrates a detailed optical structure of a warp measurement device.

FIG. 3A illustrates an example in which the wafer is in position.

FIG. 3B illustrates an example in which the wafer is out of position.

FIG. 4 illustrates a first light receiving range set on a light receiving surface of a light receiving unit.

FIG. 5 illustrates an optical structure of a warp measurement device according to a second embodiment.

FIG. 6 illustrates an example in which a light selection unit is disposed to a position that is different from the position in FIG. 5.

### DETAILED DESCRIPTION

To solve the problem, an embodiment of the present disclosure provides a warp measurement device including:

a light emitting unit that emits two optical signals having different polarization directions to an object to be measured;

a light receiving unit that receives, at different timings, the two optical signals reflected on the object to be measured; a warp detector that detects a warp of the object to be measured based on locations where the two optical signals are received on the light receiving unit; and

a light selection unit that is disposed in an optical path of the two optical signals, alternately selects the two optical signals, and guides the two optical signals into the optical path.

### First Embodiment

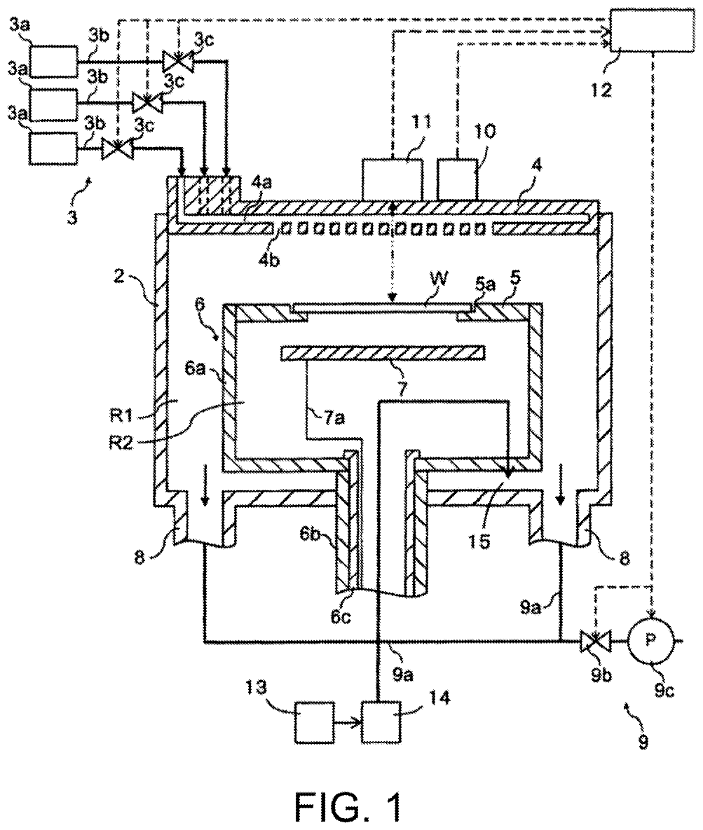

Embodiments of the present disclosure will now be described with reference to the accompanying drawings. FIG. 1 illustrates a schematic configuration of a vapor deposition apparatus 1 according to a first embodiment. In this embodiment, a silicon substrate, more specifically a silicon wafer (hereinafter simply referred to as “wafer”) W is used as the substrate on which films are deposited.

The vapor deposition apparatus 1 shown in FIG. 1 includes a chamber 2 in which films are deposited by vapor phase growth reaction on an object to be measured, which is the wafer W, a gas supply unit 3 that supplies a material gas to the wafer W in the chamber 2, a material introducing unit 4 disposed at an upper portion of the chamber 2, a susceptor 5 that supports the wafer W in the chamber 2, a rotary unit 6 that holds and rotates the susceptor 5, a heater 7 that heats the wafer W, a gas discharging portion 8 through which the gas in the chamber 2 is discharged, a discharge mechanism 9 used to discharge the gas through the gas discharging portion 8, a radiation thermometer 10 that measures the temperature of the wafer W, a warp measurement device 11 that measures the warp of the wafer W, a control unit 12 that controls the respective devices, a purge gas supply unit 13, a purge gas control unit 14, and purge gas discharge ports 15.

The chamber 2 has a shape that allows the wafer W to be housed (for example, a cylindrical shape). The susceptor 5, the heater 7, and a part of the rotary unit 6 are housed in the chamber 2.

The gas supply unit 3 includes a plurality of gas containers 3a each contains a different gas, a plurality of gas pipes 3b connecting the gas containers 3a to the material introducing unit 4, and a plurality of gas valves 3c that adjust the flow rates of the gases flowing through the gas pipes 3b. Each gas valve 3c is connected to a corresponding gas pipe 3b. The gas valves 3c are controlled by the control unit 12. The gas pipes may be arranged in various manners. For example, a plurality of gas pipes may be joined, a single gas pipe may be branched into a plurality of gas pipes, and an arrangement including both the joining and the branching gas pipes may be employed.

The material gas supplied from the gas supply unit 3 is introduced into the chamber 2 through the material introducing unit 4. The material gas (process gas) introduced into the chamber 2 is supplied above the wafer W to form a desired film on the wafer W. The type of the material gas is not limited, and may be changed according to the type the film to be deposited.

A shower plate 4a is disposed on the bottom side of the material introducing unit 4. The shower plate 4a may be formed of a metal material such as stainless steel or an aluminum alloy. The gases from the gas pipes 3b are mixed in the material introducing unit 4 and supplied to the chamber 2 through gas injection ports 4b of the shower plate 4a. The shower plate 4a may have a plurality of gas paths, through which the gases may be supplied to the wafer W in the chamber 2 without being mixed.

The structure of the material introducing unit 4 may need to be selected in consideration of the uniformity, the raw material efficiency, the reproducibility, and the manufacturing costs of the deposited film, but is not limited if such requirements are met. Thus, a known structure may be arbitrarily used.

The susceptor 5 is disposed at an upper portion of the rotary unit 6, and has a structure that allows the wafer W to be put in and supported by a recessed portion formed at an inner periphery side of the susceptor 5. The susceptor 5 has a ring shape having an opening at the central portion in the example of FIG. 1, but may have a substantially flat-plate shape with no opening.

The heater 7 is a heating unit for heating the susceptor 5 and/or the wafer W. The structure of the heating unit is not limited if the requirements such as the durability and the ability to heat an object to be heated until a desired temperature and desired temperature distribution are reached. Specifically, the heating unit may use resistance heating, lamp heating, or induction heating.

The discharge mechanism 9 discharges the reacted material gas from the inside of the chamber 2 through the gas discharging portion 8, and controls the pressure in the chamber 2 to have a desired value by means of a gas discharge valve 9b and a vacuum pump 9c.

The radiation thermometer 10 is disposed on the top surface of the material introducing unit 4. The radiation thermometer 10 emits light from a light source (not shown) to the wafer W and receives a reflected light from the wafer W to measure the intensity of the reflected light from the wafer W. The radiation thermometer 10 also receives a thermal radiation light from a film growth surface Wa of the wafer W to measure the intensity of the thermal radiation light. Although FIG. 1 shows only one radiation thermometer 10, a plurality of radiation thermometers 10 may be disposed on the top surface of the material introducing unit 4 to measure the temperatures of a plurality of portions (for example, the inner periphery side and the outer periphery side) of the film growth surface Wa of the wafer W.

A light transmission window is formed on the top surface of the material introducing unit 4, which transmits lights from the radiation thermometer 10 and a light source of a warp measurement device 11 that will be described later, and the reflected light and the thermal radiation light from the wafer W. The light transmission window may have an arbitrary shape such as a slit shape, a rectangular shape, or a circular shape. The light transmission window is formed of a material that is transparent to lights in a wavelength range measured by the radiation thermometer 10 and the warp measurement device 11. To measure the temperature from an ambient temperature to about 1500 degrees, the lights to be measured are preferably in a wavelength region from the visible region to the near-infrared region. In such a case, the light transmission window may be preferably formed of quartz.

The control unit 12 includes a computer (not shown) that controls respective units of the vapor deposition apparatus 1 and a memory unit (not shown) that stores film deposition process information and programs for depositing films. The control unit 12 controls the gas supply unit 3, the rotation mechanism of the rotary unit 6, and the discharge mechanism 9 based on the film deposition process information and the programs, and controls the heating of the wafer W by means of the heater 7.

The purge gas supply unit 13 supplies a purge gas to the chamber 2 under control of the purge gas control unit 14. The purge gas is, for example, an inert gas for preventing the deterioration of the heater 7. The purge gas discharge ports 15 are disposed to a plurality of portions of the bottom of the rotary unit 6.

As will be described later, the warp measurement device 11 measures the warp of the wafer W disposed on the susceptor 5. The wafer W may warp upward or downward. In any case, the warp measurement device 11 can measure the warp of the wafer W. The warp measurement device 11 may have a function of detecting that the wafer W on the susceptor 5 is out of position. The “out of position” state of the wafer W means that the wafer W is disposed to be inclined relative to the wafer mounting surface of the susceptor 5.

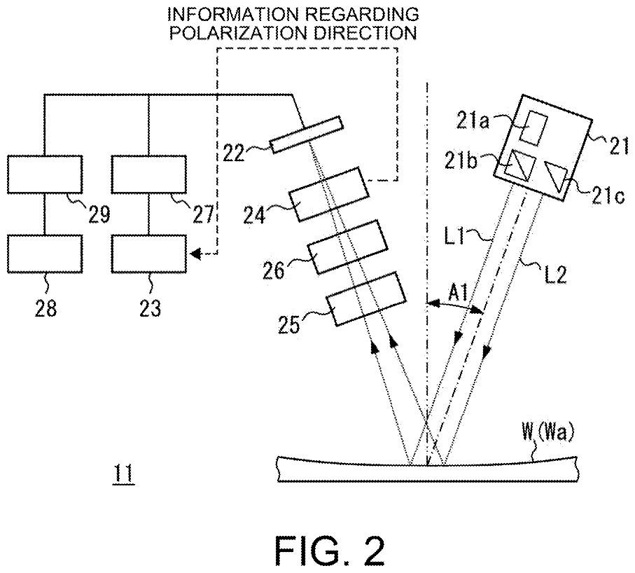

FIG. 2 illustrates a detailed optical structure of the warp measurement device 11. The warp measurement device 11 includes a light emitting unit 21, a light receiving unit 22, a warp detector 23, and a light selection unit 24. The warp measurement device 11 shown in FIG. 2 may also include an optical filter 25, a condenser lens 26, and a first light receiving range determination unit 27. The warp measurement device 11 shown in FIG. 2 may further include a position shift detector 28.

The light emitting unit 21 emits two optical signals each having a different polarization direction toward the wafer W. The optical signals emitted from the light emitting unit 21 are preferably laser beams having the same phase and the same frequency. In the example of FIG. 2, the light emitting unit 21 emits two laser beams toward the film growth surface Wa of the wafer W.

The light emitting unit 21 includes a light emitter 21a, a polarizing beam splitter 21b, and a mirror 21c. The polarizing beam splitter 21b divides a laser beam emitted from the light emitter 21a into a laser beam with S polarization component and a laser beam with P polarization component. The laser beam with S polarization component (“first laser beam”) L1 is directly incident on the film growth surface Wa of the wafer W, and the laser beam with P polarization component (“second laser beam”) L2 is first reflected on the mirror 21c to become substantially in parallel to the first laser beam L1, and then incident on the film growth surface Wa of the wafer W. The phrase “substantially in parallel” herein means that the first laser beam L1 and the second laser beam L2 may not be parallel to each other in a strict sense. However, the first laser beam L1 and the second laser beam L2 are preferably parallel to each other as much as possible.

The first laser beam L1 and the second laser beam L2 are incident on, for example, a central portion of the film growth surface Wa of the wafer W. The incident angle A1 of the laser beams L1 and L2 is preferably at least equal to or less than 20 degrees. It is desirable to use laser beams which have a wavelength of, for example, equal to or less than 700 nm, more preferably equal to or less than 600 nm (for example, 532 nm), because it would be easier to avoid influence from light emission from red-hot wafer W due to small thermal radiation from the wafer W at the wavelength and due to high sensitivity of a silicon-based detector at the wavelength.

To avoid the interference of light caused by the film deposited on the wafer W, which is the object to be measured, it would be effective to use laser beams having a wavelength that allows the deposited film to absorb the laser beams in this embodiment. More specifically, laser beams having energy that is higher than the band gap of the deposited film may be used. If the deposited film absorbs the laser beams of this embodiment, as the film thickness increases, the interference decreases. When the thickness becomes greater than a certain level, no interference occurs. For example, if a GaN film is present, GaN has the optical absorption edge in the ultraviolet region (365 nm), but when the temperature is equal to or higher than 700° C., GaN absorbs lights in the blue-violet region since its band gap becomes smaller. Therefore, if the GaN film is formed at a temperature equal to or higher than 700° C., the interference of light caused by GaN may be reduced by using laser beam having a wavelength of 405 nm in this embodiment.

The light receiving unit 22 receives the two optical signals (first laser beam L1 and second laser beam L2) reflected on the object to be measured such as the wafer W at different timings. This enables the single light receiving unit 22 to receive the first laser beam L1 and the second laser beam L2, and eliminates the need of providing a light receiving unit for every laser beam. As the result, the optical structure may be simplified.

The light receiving unit 22 has a function to detect where the first laser beam L1 and the second laser beam L2 are incident. A specific example of the light receiving unit 22 is a semiconductor position sensitive detector (PSD). The PSD obtains the center of gravity (position) in the distribution of the incident laser beams (spot light amount), and outputs two electrical signals (analog signals) representing the center of gravity. The PSD is sensitive to light in the visible light range. In the vapor deposition apparatus 1 according to this embodiment, the wafer W is heated to become red, and therefore emits red light. If the wafer W is only heated to emit red light, the use of green laser beam may avoid the problem since the intensity of the laser beam is considerably stronger than the intensity of red light emitted from the wafer W. However, when a film is deposited in the vapor deposition apparatus 1 according to this embodiment, there is a timing at which substantially no laser beam is reflected due to the interference of the laser beam caused by the film. At such a timing, the intensity of red light is greater than the intensity of the reflected laser beam. As the result, the position of the reflected laser beam from the object to be measured (wafer W) cannot be accurately measured or cannot be measured at all on the light receiving unit 22. To prevent this, the optical filter 25 that does not allow any light of wavelength other than that of the laser beams used in this embodiment to pass therethrough is preferably used. Other examples of the light receiving unit 22 include a solid-state imaging device (such as CCD or CMOS) capable of detecting the position where the light is received.

The light selection unit 24 is disposed in the optical path between the light emitting unit 21 and the light receiving unit 22 (including the inside of the light emitting unit 21 and the inside of the light receiving unit 22). The light selection unit 24 alternately selects the two optical signals and guides the two optical signals into the optical path. As will be described later, the light selection unit 24 may include such components as a Pockeles cell, a polarization shutter, a liquid crystal shutter, and a ½ wavelength plate. Since the two optical signals propagating in the optical path have different polarization directions in this embodiment, the light selection unit 24 selects one of the two optical signals having the different polarization directions at a time and guides the selected one into the optical path, i.e., alternately selects one of the two optical signals.

Preferably, the light selection unit 24 transmits, to the warp detector 23, information on which of the two optical signals having the different polarization directions is selected. Alternatively, a controller (not shown) configured to control the light selection unit 24 to select one of the two optical signals having the different polarization directions may send the above-described information to the warp detector 23.

Furthermore, preferably, the light selection unit 24 may select one of the two optical signals having different polarization directions for a longer period than the other.

As described above, in FIG. 2, the light emitting unit 21 emits the two optical signals to the object to be measured (wafer W) at the same timing, and the light selection unit 24 selects one of the two optical signals reflected on the object to be measured at a time, and guides the two optical signals at different timings in the optical path. More specifically, the light emitting unit 21 emits the two optical signals, one having a first polarization direction and the other having a second polarization direction, at the same timing, and the light selection unit 24 has a function to select and guide into the optical path the optical signal having the first polarization direction and the optical signal having the second polarization direction at different timings

The optical filter 25 is disposed in the optical path where the first laser beam L1 and the second laser beam L2 reflected on the wafer W propagate in a substantially parallel manner.

The optical filter 25 cuts (removes) lights other than lights having the wavelength component of the first laser beam L1 and the second laser beam L2. The optical filter 25 may be, for example, a monochromatic filter. Due to the existence of the optical filter 25, no light enters the light receiving unit 22 other than lights having the same wavelength component (in the above example, green) of the laser beams L1 and L2. The influence of the light emission from the red-hot wafer W may be avoided and the position detection accuracy may be improved in this manner.

The condenser lens 26 may be disposed between the wafer W and the light-receiving surface of the light receiving unit 22 of the light receiving unit 22 to adjust the position and the shape of the reflected laser beam from the wafer W. The condenser lens 26 is disposed in the optical path where the first laser beam L1 and the second laser beam L2 reflected on the wafer W propagate substantially in parallel to each other. Typically, the condenser lens 26 is disposed between the optical filter 25 and the light receiving unit 22. The condenser lens 26 focuses the first laser beam L1 and the second laser beam L2 on the light-receiving surface of the light receiving unit 22. The condenser lens 26 may be a semi-cylindrical lens.

In the example of FIG. 1, the light selection unit 24 is disposed between the condenser lens 26 and the light receiving unit 22. However, the light selection unit 24 may be arbitrarily disposed in the optical path of the first laser beam L1 and the second laser beam L2, and FIG. 1 only shows an example of the location of the light selection unit 24.

The light receiving unit 22 is a position sensitive detector that receives the first laser beam L1 and the second laser beam L2 at different timings, and detects the locations where the respective light beams are received. The normal of the light-receiving surface of the light receiving unit 22 may be inclined by 10 to 20 degrees relative to the optical axis of the first laser beam L1 and the second laser beam L2.

By inclining the normal of the light-receiving surface of the light receiving unit 22 relative to the direction of the incident laser beams, the laser beam reflected on the light receiving unit 22 does not return to the optical system, i.e., no return light is generated. The return light acts as noise to the reflected light from the object to be measured which is used in the present disclosure. Since the light reflected from the light receiving unit 22 (return light) is prevented from returning to the optical path by inclining the light-receiving surface of the light receiving unit 22 relative to the propagating direction of the first laser beam L1 and the second laser beam L2, lowering the accuracy of the position detection caused by the light reflected (return light) is prevented.

The first light receiving range determination unit 27 determines whether the first laser beam L1 and the second laser beam L2 are incident within a first light receiving range. If the first light receiving range determination unit 27 determines that the first laser beam L1 and the second laser beam L2 are incident within the first light receiving range, the warp detector 23 detects the degree of the warp of the wafer W based on the locations where the first laser beam L1 and the second laser beam L2 are received on the light-receiving surface of the light receiving unit 22. The warp detector 23 may determine which of the first laser beam L1 and the second laser beam L2 is received by the light receiving unit 22 based on information from the light selection unit 24, for example. If the light selection unit 24 selects one of the two optical signals having different polarization directions for a longer period than the other, the warp detector 23 may determine which of the first laser beam L1 and the second laser beam L2 is received by the light receiving unit 22 based on the difference in detection time between the first laser beam L1 and the second laser beam L2.

For example, the warp detector 23 calculates the difference between the amount of change in the location where the first laser beam L1 is received and the amount of change in the location where the second laser beam L2 is received, the locations being detected by the light receiving unit 22, and calculates the change in curvature of the wafer W based on the correlation between the calculated difference and the respective optical path lengths of the first laser beam L1 and the second laser beam L2. The curvature before the locations are changed may be converted to an absolute value of the radius of curvature based on a calibration mirror or a substrate that does not have a warp.

The correlation is represented by a predetermined relational expression. An example of the relational expression is (X1+X2)/2=w×Y×Z1 where X1 denotes the amount of change in the location of the laser beam L1, X2 denotes the amount of change in the location of the laser beam L2, Y denotes the optical path length of each of the laser beams L1 and L2 (Y1 denotes the optical path length of the laser beam L1 and Y2 denotes the optical path length of the laser beam L2, but they are considered to be substantially the same amount Y), Z1 denotes the amount of change in curvature, and w denotes the distance between the locations where the two laser beams hit the object to be measured. The signs of X1 and X2 are set so that the changes in location toward the midpoint between the two laser beams are indicated by the same sign.

It may not be practical to strictly measure w and Y. However, these values may not be considerably changed during the measurement. Therefore, in a simple relation that the total amount of changes in location (i.e., the changes in geometric distance between the two laser beams) is proportional to the curvature represented by the equation “Xtotal=C×Z1 (Xtotal=X1+X2),” C can be determined by means of calibration mirrors (two types) having a known radius of curvature. One of the two types of calibration mirrors preferably have a radius of curvature that is as infinite as possible (i.e., a flat surface), and the other preferably has a lowest possible radius of curvature. If possible, a third mirror having an intermediate radius of curvature is also used for measurement to confirm that a linear relationship is held in the measurement range (if the calibration curve is made for Z1).

The warp detector 23 preferably captures the signals from the light receiving unit 22 at predetermined timings. For example, the warp detector 23 captures a phase signal relating to a periodical movement of the wafer W and captures a signal from the light receiving unit 22, and calculates the curvature only using the location signal in an arbitrary phase range in the periodical movement. If the periodical movement is a rotational movement, for example, the warp detector 23 captures a signal from the light receiving unit 22 in synchronization with each rotation of the motor of the rotation mechanism (the pulse in z phase of the motor). The location signal may be a value obtained at an arbitrary timing or an average value obtained over an arbitrary range of time. More preferably, the location signal may be obtained by integrating these values. If it is difficult to do so, it is recommended to obtain a value of the location signal by averaging the information captured over a plurality of rotation cycles.

As the number of films deposited on the wafer W or the thickness of the films increases, the warp of the wafer W also increases. Therefore, it is preferable that the warp measurement device 11 measures the warp repeatedly during the deposition of films on the wafer W. The warp measurement cycle in a single wafer type vapor deposition apparatus, for example, is preferably within 10 seconds. In practice, the warp measurement cycle is preferably determined in consideration of the film deposition rate on the wafer W or the change in temperature in the chamber 2.

Films are often deposited on the wafer W while the wafer W is being rotated. When the first laser beam L1 and the second laser beam L2 are emitted toward positions that are apart from the center of the wafer W, if the wafer W is greatly rotated after one of the laser beam is emitted and before the other laser beam is emitted, the warp cannot be measured precisely. Therefore, it is preferable to complete one cycle of warp measurement by emitting the first laser beam L1 and the second laser beam L2 within a period during which 1/10 of the wafer W is rotated.

If a plurality of wafers W are put on the susceptor 5 and films are deposited while the wafers W are rotated, the interval between the emission of the first laser beam L1 and the emission of the second laser beam L2 needs to be adjusted in accordance with the rotational speed of the susceptor 5 so that the warp of each wafer W may be measured at the same position in each cycle.

The wafer W may be rotated with the normal of the wafer W being inclined relative to the rotation axis of the susceptor 5. Therefore, it is preferable that the interval between the emission of the first laser beam L1 and the emission of the second laser beam L2 is as short as possible.

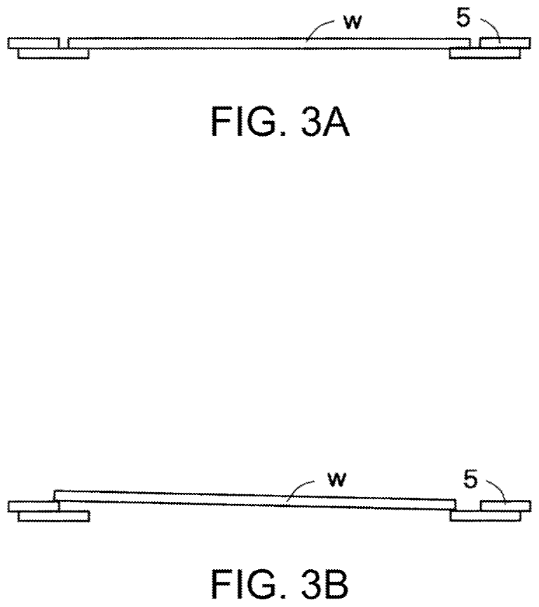

The warp measurement device 11 may be used to detect whether the wafer W is out of position. FIG. 3A illustrates an example in which the wafer W is in position, and FIG. 3B illustrates an example in which the wafer W is out of position. The wafer W is out of position when it is on the edge portion of the susceptor 5 as shown in FIG. 3B. The case shown in FIG. 3B may be caused due to the positioning failure when the wafer W is put into the chamber 2 by means of robot arms. The wafer W may also become out of position when the pressure condition within the chamber 2 is changed after the wafer W is correctly placed on the susceptor 5.

If films are deposited on the wafer W while the wafer W is out of position, it is difficult to form a uniform film having a predetermined thickness accurately. Therefore, in this embodiment, the film deposition process is stopped when the warp measurement device 11 detects that the wafer W is out of position, and the wafer W is taken out of the chamber 2.

The warp measurement device 11 for detecting whether the wafer W is out of position includes the position shift detector 28, and a second light receiving range determination unit 29 as shown in FIG. 2.

The second light receiving range determination unit 29 determines whether the location where the first laser beam L1 emitted from the light receiving unit 22 and the location where the second laser beam L2 also emitted from the light receiving unit 22 are outside the predetermined first light receiving range.

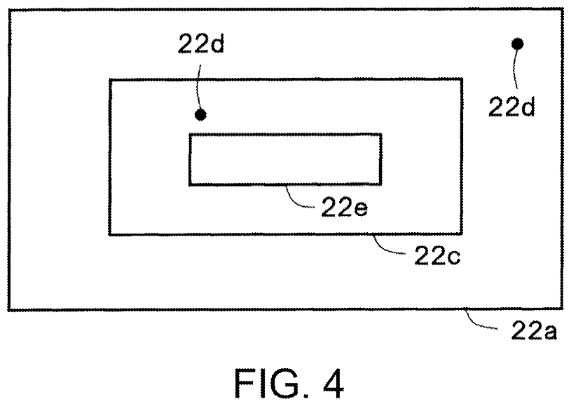

FIG. 4 illustrates a first light receiving range 22c set on the light-receiving surface of the light receiving unit 22. If the wafer W is placed at a predetermined position on the susceptor 5, the first laser beam L1 is always incident within the first light receiving range 22c. If the bottom of the wafer W is in contact with the edge of the susceptor 5, and the wafer W is inclined relative to the susceptor 5, the first laser beam L1 is incident at a position outside the first light receiving range 22c. FIG. 4 shows the case where a beam spot 22d of the first laser beam is within the first light receiving range 22c, and the case where the beam spot 22d is outside the first light receiving range 22c.

If the inclination angle of the wafer W relative to the wafer mounting surface of the susceptor 5 is large, the first laser beam L1 and the second laser beam L2 may not be received by the light receiving unit 22. Also in such a case, the second light receiving range determination unit 29 determines that the locations where the first laser beam L1 and the second laser beam L2 are incident are outside the first light receiving range 22c.

If the second light receiving range determination unit 29 determines that the locations where the first laser beam L1 and the second laser beam L2 are incident are outside the first light receiving range 22c, the position shift detector 28 determines that the wafer W is out of position.

When the position shift detector 28 detects that the wafer W is out of position, the control unit 12 stops the film deposition process performed on the wafer W mounted on the susceptor 5, and rotates the rotary unit 6 so that the wafer W is rotated to a rotation position where the wafer W can be taken out of chamber 2. The wafer W is then taken out of the chamber 2. For example, the wafer W taken out of the chamber 2 is discarded. If the wafer W is not determined to be out of position until the previous step, the wafer W may be once taken out of the chamber 2 and then put on the susceptor 5 in the chamber 2 again, and the film deposition process may be restarted from the step at which the wafer W is determined to be out of position. If the light receiving unit 22 does not receive the first laser beam L1 and the second laser beam L2, the light receiving unit 22 determines that something such as a crack may be caused to the wafer W, and stops the process performed on the wafer W. If a broken piece of the wafer W is left in the chamber 2, such a piece is collected.

As described above, in the first embodiment, the light selection unit 24 is disposed in the optical path of the two optical signals used for optically measuring the warp of the object to be measured, the two optical signals having different polarization directions. The light selection unit 24 causes the two optical signals reflected on the object to be measured to be incident on the light receiving unit 22 at different timings. Therefore, the warp of the wafer W may be measured with a single light receiving unit 22 that receives the two optical signals. Thus, the optical structure of the warp measurement device 11 can be simplified.

### Second Embodiment

In the first embodiment, the light selection unit 24 is disposed on the optical path after the two optical signals are reflected on the wafer W. However, the light selection unit 24 may be disposed on the optical path before the two optical signals are reflected on the wafer W.

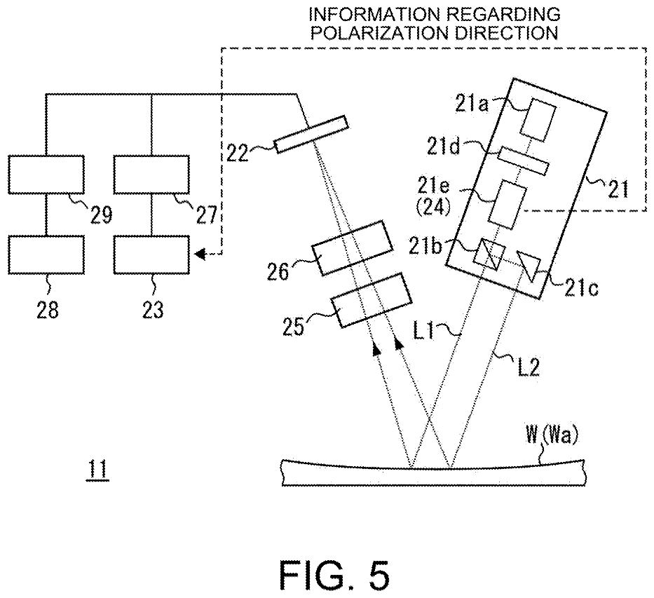

FIG. 5 illustrates an optical structure of a warp measurement device according to a second embodiment. The location of the light selection unit 24 in the warp measurement device shown in FIG. 5 is different from the location of the light selection 24 shown in FIG. 2. Furthermore, the internal structure of the light emitting unit 21 according to the second embodiment is different from the internal structure of the light emitting unit 21 shown in FIG. 2.

In the warp measurement device shown in FIG. 5, the light selection unit 24 is disposed in the light emitting unit 21. The light emitting unit 21 shown in FIG. 5 includes a light emitter 21a, a polarizing beam splitter 21b, and a mirror 21c as in the case of FIG. 2, and additionally includes a polarizer 21d and a Pockeles cell 21e. The polarizer 21d and the Pockeles cell 21e constitute the light selection unit 24.

The polarizer 21d transmits only a specific polarization component included in an optical signal emitted from the light emitter 21a. A high voltage pulse is applied to the Pockeles cell 21e. The Pockeles cell 21e is an electro-optic modulator in which the refractive index of a non-centrosymmetric crystal is changed linearly when the voltage is applied. Thus, the Pockeles cell 21e can switch the polarization direction of an optical beam depending on whether the voltage is applied. While the high voltage pulse is not applied, the Pockeles cell 21e outputs the inputted optical signal without changing its polarization component, and while the high voltage pulse is applied, the Pockeles cell 21e outputs an optical signal obtained by changing the polarization component of the inputted optical signal by 90 degrees.

For example, if the polarizer 21d transmits the optical signal having the S polarization component, the Pockeles cell 21e outputs an optical signal having the S polarization component while the high voltage pulse is not applied, and outputs an optical signal having the P polarization component while the high voltage pulse is applied.

The optical signals outputted from the Pickles cell 21e are inputted to the polarizing beam splitter 21b. The polarizing beam splitter 21b separates the optical signal having the S polarization component and the optical signal having the P polarization component. Thereafter, the light emitting unit 21 outputs the optical signal having the S polarization component and the optical signal having the P polarization component at different timings.

As described above, the light selection unit 24 (Pockeles cell 21e) shown in FIG. 5 alternately switches the operation in which the optical signal having the specific polarization component is outputted as it is, and the operation in which the optical signal having a polarization component that is different from the specific polarization component is outputted. The light emitting unit 21 outputs the two optical signals that the light selection unit alternately selects at different timings.

In the warp measurement device shown in FIG. 5, the first laser beam L1 and the second laser beam L2 are incident and reflected on the wafer W at different timings, and received by the light receiving unit 22 via the optical filter 25 and the condenser lens 26.

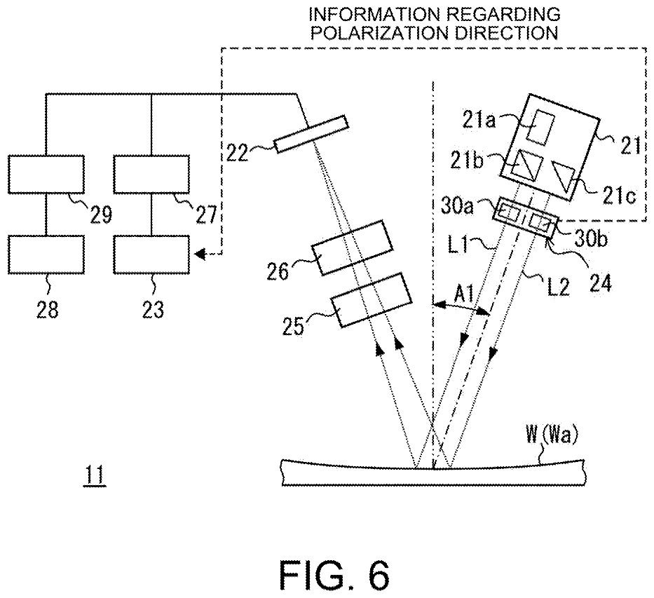

FIG. 5 shows an example in which the light selection unit 24 is included in the light emitting unit 21. However, the light selection unit 24 may be disposed between the light emitting unit 21 and the wafer W, i.e., before the first laser beam L1 and the second laser beam L2 emitted from the light emitting unit 21 hit the wafer W, as shown in FIG. 6. In the case shown in FIG. 6, the light selection unit 24 includes two liquid crystal shutters (first liquid crystal shutter 30a and second liquid crystal shutter 30b), for example. The first liquid crystal shutter 30a electrically switches the operation in which the first laser beam L1 having the S polarization component emitted from the light emitting unit 21 is transmitted and the operation in which it is blocked. The second liquid crystal shutter 30b electrically switches the operation in which the second laser beam L2 having the P polarization component emitted from the light emitting unit 21 is transmitted and the operation in which it is blocked. The timing at which the first liquid crystal shutter 30a transmits the laser beam L1 and the timing at which the second liquid crystal shutter 30b transmits the laser beam L2 are alternately selected. In this manner, the timings of the laser beams incident on the wafer W may be differentiated.

Preferably, in both the cases shown in FIGS. 5 and 6, the light selection unit 24 transmits, to the warp detector 23, information on which of the two optical signals having the different polarization directions is selected. Alternatively, a controller (not shown) configured to control the light selection unit 24 to select one of the two optical signals having the different polarization directions may send the above-described information to the warp detector 23. Furthermore, preferably, in both the cases shown in FIGS. 5 and 6, the light selection unit 24 may select one of the two optical signals having different polarization directions for a longer period than the other.

The warp detector 23 may determine which of the first laser beam L1 and the second laser beam L2 is emitted based on such information.

FIGS. 2, 5, and 6 only illustrate typical examples of the light selection unit 24. Where in the optical path the light selection unit 24 is disposed, and what optical element is used as the light selection unit 24 may be arbitrarily determined.

For example, a single liquid crystal shutter having a size that allows the first laser beam L1 and the second laser beam L2 to be transmitted simultaneously may be used instead of the two liquid crystal shutters 30a and 30b used in FIG. 6. Generally, a liquid crystal shutter includes a liquid crystal portion that rotates the polarization and a light analyzing portion that transmits light polarized in one direction. If a single liquid crystal shutter controls the polarization as described above, the light analyzing portion is not necessarily disposed to be adjacent to the liquid crystal portion, but may be disposed at an arbitrary location between the liquid crystal portion and the light receiving unit 22.

While certain embodiments have been described, these embodiments have been presented by way of example only, and are not intended to limit the scope of the disclosures. Indeed, the novel methods and systems described herein may be embodied in a variety of other forms; furthermore, various omissions, substitutions and changes in the form of the methods and systems described herein may be made without departing from the spirit of the disclosures. The accompanying claims and their equivalents are intended to cover such forms or modifications as would fail within the scope and spirit of the disclosures.

1. A warp measurement device comprising:
a light emitter that emits two optical signals having different polarization directions to an object to be measured;
a light receiver that receives, at different timings, the two optical signals reflected on the object to be measured;
a warp detector that detects a warp of the object to be measured based on locations where the two optical signals are received on the light receiver; and
a light selector that is disposed in an optical path of the two optical signals, alternately selects the two optical signals, and guides the two optical signals into the optical path.

2. The warp measurement device according to claim 1, wherein the light selector is disposed in the optical path between the light emitter and the light receiver.

3. The warp measurement device according to claim 1, wherein:
the light selector alternately selects a first laser beam that is a linearly polarized light and a second laser beam that is polarized in a direction perpendicular to a polarization direction of the first laser beam, and guides the first laser beam and the second laser beam into the optical path; and
the warp detector detects the warp of the object to be measured based on a location where the first laser beam is received and a location where the second laser beam is received, the first laser beam and the second laser beam being received at different timings.

4. The warp measurement device according to claim 1, wherein:
the light emitter emits the two optical signals toward the object to be measured at the same timing; and
the light selector selects the two optical signals reflected on the object to be measured at different timings when guiding the two optical signals into the optical path.

5. The warp measurement device according to claim 4, wherein:
the light emitter emits the two optical signals at the same timing, one optical signal having a first polarization direction and another optical signal having a second polarization direction; and
the light selector selects the one optical signal having the first polarization direction and the other optical signal having the second polarization direction at different timings when guiding the two optical signals into the optical path.

6. The warp measurement device according to claim 1, wherein the light selector alternately selects whether an optical signal having a predetermined polarization component is emitted or an optical signal having another polarization component that is different from the predetermined polarization component is emitted.

7. The warp measurement device according to claim 5, wherein the light emitter emits the two optical signals, which are alternately selected by the light selector, at different timings.

8. A vapor deposition apparatus comprising:
a reaction chamber in which a vapor phase growth reaction is caused to a substrate;
a gas supplier that supplies a gas to the reaction chamber;
heating means that heats the substrate from a side that is opposite to a film growth surface of the substrate;
a light emitter that emits two optical signals having different polarization directions to the film growth surface;
a light receiver that receives, at different timings, the two optical signals reflected on the film growth surface;
a warp detector that detects a warp of the substrate based on locations where the two optical signals are received at the light receiver; and
a light selector that is disposed in an optical path of the two optical signals, alternately selects the two optical signals, and guides the two optical signals into the optical path.

9. The vapor deposition apparatus according to claim 8, wherein the light selector is disposed in the optical path between the light emitter and the light receiver.

10. The vapor deposition apparatus according to claim 8, wherein:
the light selector alternately selects a first laser beam that is a linearly polarized light polarized in one direction and a second laser beam that is polarized in a direction perpendicular to the one direction in which the first laser beam is polarized, and guides the first laser beam and the second laser beam into the optical path; and
the warp detector detects the warp of the substrate to be measured based on a location where the first laser beam is received and a location where the second laser beam is received, the first laser beam and the second laser beam being received at different timings.

11. The vapor deposition apparatus according to claim 8, wherein
the light emitter emits the two optical signals toward the substrate to be measured at the same timing; and
the light selector selects the two optical signals reflected on the substrate to be measured at different timings when guiding the two optical signals into the optical path.

12. The vapor deposition apparatus according to claim 11, wherein:
the light emitter emits the two optical signals, one optical signal having a first polarization direction and another optical signal having a second polarization direction; and
the light selector selects the one optical signal having the first polarization direction and the other optical signal having the second polarization direction at different timings when guiding the two optical signals into the optical path.

13. The vapor deposition apparatus according to claim 8, wherein the light selector alternately selects whether an optical signal having a predetermined polarization component is emitted or an optical signal having another polarization component that is different from the predetermined polarization component is emitted.

14. The vapor deposition apparatus according to claim 13, wherein the light emitter emits the two optical signals, which are alternately selected by the light selector, at different timings.

15. A warp measurement method comprising:
emitting two optical signals having different polarization directions to an object to be measured;
alternately selecting the two optical signals and guiding the two optical signals into an optical path;
receiving, at different timings, the two optical signals reflected on the object to be measured; and
detecting a warp of the object to be measured based on locations where the two optical signals are received.

16. The warp measurement method according to claim 15, wherein the two optical signals are alternately selected after the two optical signals are emitted toward the object to be measured and before the two optical signals are received.

17. The warp measurement method according to claim 15, wherein:
a first laser beam, which is a linearly polarized light polarized in one direction, and a second laser beam, which is polarized in a direction perpendicular to the one direction in which the first laser beam is polarized, are alternately selected and guided into the optical path; and
the warp of the object to be measured is detected based on a location where the first laser beam is received and a location where the second laser beam is received, the first laser beam and the second laser beam being received at different timings.

18. The warp measurement method according to claim 15, wherein:
the two optical signals are emitted toward the object to be measured at the same timing; and
the two optical signals reflected on the object to be measured are selected and guided into the optical path at different timings.

19. The warp measurement method according to claim 18, wherein
the two optical signals, which is a first optical signal having a first polarization direction and a second optical signal having a second polarization direction, are emitted at the same timing; and
the first optical signal having the first polarization direction and the second optical signal having the second polarization direction are selected and guided into the optical path at different timings.

20. The warp measurement method according to claim 15, wherein whether an optical signal having a specific polarization component is emitted or an optical signal having another polarization component obtained by changing the specific polarization component is emitted is alternately selected.
